(19) United States
(12) Patent Application Publication
(10) Pub. No.: US 2016/0181570 A1
(43) Pub. Date: Jun. 23, 2016

(54) ORGANIC LIGHT EMITTING DIODES

(71) Applicant: EPIRE TECHNOLOGY DEVELOPMENT LLC, Wilmington, DE (US)

(72) Inventors: Georgius Abidal ADAM, Edensor Park, New South wales (AU); William Brenden CARLSON, Seattle, WA (US); Christopher John BUNTEL, Singapore (SG); Kenichi HASHIZUME, Kitagunma-gun, Gunma (JP); Vincenzo CASASANTA, III, Woodinville, WA (US)

(73) Assignee: EPIRE TECHNOLOGY DEVELOPMENT LLC, Wilmington, DE (US)

(21) Appl. No.: 14/905,600

(22) PCT Filed: Jul. 15, 2013
(86) PCT No.: PCT/US13/50448

§ 371 Date: Jan. 15, 2016

(51) Int. Cl. H01L 51/52; H01L 51/56; C09D 131/04; H01L 51/00

(52) U.S. Cl. CPC H01L 51/5253; H01L 51/0043; H01L 51/004; H01L 51/56; H01L 51/0094; C09D 131/04

(57) ABSTRACT

Organic light emitting diodes (OLEDs) include a polymeric barrier coating that is a copolymer of ethylene and substituted vinyl constituents configured to protect the OLEDs from both oxygen and water. The substituted vinyl of the coating may be selected, in conjunction with the permeability properties provided by the ethylene, to include chemical structures, physical structures, and chemical functional groups that effectively and efficiently create a barrier towards both oxygen and water. Methods for producing and using the coatings are also disclosed.

### BACKGROUND

An OLED (organic light-emitting diode) is a light-emitting diode (LED) in which the emissive electroluminescent layer is provided by films of organic compounds which emit light in response to an electric current. The organic material is electrically conductive due to the delocalization of pi electrons caused by conjugation over all or part of the molecule, and the material therefore functions as an organic semiconductor. The organic materials can be small organic molecules in a crystalline phase, or polymers. The organic films may include a hole-injection layer, a hole-transport layer, an emissive layer and an electron-transport layer. When voltage is applied to the OLED cell, the injected positive and negative charges recombine in the emissive layer and create electroluminescent light. The layer of organic semiconductor is situated between two charged electrodes, at least one of which may be transparent.

OLEDs are usable for creating digital displays in devices such as television screens, computer monitors, and portable systems such as mobile phones, handheld games consoles, and PDAs. OLEDs are able to provide several advantages over the more commonly used LCDs (liquid crystal displays) used for digital displays. The polymeric, organic layers of an OLED are thinner, lighter and more flexible than the crystalline layers in an LED or LCD. OLEDs are lighter, and the substrate may therefore be thinner and/or flexible. OLEDs provide brighter emissions and do not require backlighting, thereby providing displays that consume less power and provide deeper dark colors to provide improved contrast ratios. OLEDs are also easier to produce and can be made to larger sizes. Because OLEDs are plastic, they can be made into large, thin sheets.

However, OLEDs are readily degraded by the abundant atmospheric components oxygen and water, and protection from at least oxygen and water thereby poses a challenge to the use of OLEDs in displays. When exposed to water and oxygen the organic layers can become hydrated and/or oxidized, and OLEDs can cease to function when this happens. Unlike many other electronic devices, OLEDs can be destroyed by water and oxygen whether they are turned off or turned on. Thus, an OLED can cease to function without ever having electric current pass through it.

Several types of polymeric resins have been evaluated as barrier materials for OLED applications. Some of these resin families include epoxy resins, polyacrylonitrile, polyvinylalcohol and its copolymers, polylactide, polyethylene terephthalate, polyvinylidine dichloride, liquid crystal polymers, silicone polymers, polyethylenes, and others. However, none of these polymeric barriers provide the necessary impermeability toward both oxygen and water to allow for a long device lifetime.

There remains a need for a dual-acting coating material that may be applied to OLEDs to minimize or completely inhibit degradation that may be caused by oxygen and water, and which may also be applied easily to the OLED without damaging the OLED, creating thermal stresses, or leading to thermal degradation.

### SUMMARY

Disclosed herein are OLEDs resistant to oxygen and water degradation. Embodiments include OLEDs coated with a polymeric barrier material that is based on a copolymer of ethylene and substituted vinyl, to thereby protect the OLEDs from both oxygen and water. The vinyl substituents of the substituted vinyl may be selected, in conjunction with the permeability properties provided by the ethylene, to include chemical structures, physical structures, and chemical functional groups that effectively and efficiently create a barrier towards both oxygen and water permeation.

In an embodiment, a coated organic light-emitting diode includes at least one organic light-emitting diode, and an oxygen and water resistant coating on the organic light-emitting diode. The coating includes a copolymer of ethylene and substituted vinyl, wherein the substituted vinyl includes at least one hydrophobic substituent.

In an embodiment, an oxygen and water resistant coating composition includes a copolymer of ethylene and substituted vinyl, wherein the substituted vinyl includes at least one hydrophobic substituent.

In an embodiment, a method for protecting an organic light-emitting diode from degradation by oxygen and water includes coating the organic light emitting diode with an oxygen and water resistant coating and curing the coating. The coating includes a copolymer of ethylene and substituted vinyl, wherein the substituted vinyl includes at least one hydrophobic substituent.

In an embodiment, a kit for producing an oxygen and water resistant coating includes copolymers of ethylene and substituted vinyl, and hydrophobic moieties for functionalizing at least a portion of the substituted vinyl.

In an embodiment, a method for producing an oxygen and water resistant coating includes forming a copolymer of ethylene and substituted vinyl, wherein the substituted vinyl includes at least one hydrophobic substituent.

In an embodiment, a coated organic light-emitting diode includes an organic light-emitting diode, and an oxygen and water resistant coating that includes cross-linked copolymers of ethylene and substituted vinyl, wherein the substituted vinyl includes a at least one vinyl substituent that is oxygen and water resistant.

In an embodiment, an oxygen and water resistant coating includes cross-linked copolymers of ethylene and substituted vinyl, wherein the substituted vinyl includes at least one vinyl substituent that is oxygen and water resistant.

In an embodiment, a method for protecting an organic light-emitting diode from oxygen and water degradation includes producing an oxygen and water resistant coating, coating the organic light emitting diode with the oxygen and water resistant coating, and curing the coating composition to cross-link the copolymers. The producing of the coating includes mixing at least one copolymer of ethylene and substituted vinyl, wherein the substituted vinyl includes at least one vinyl substituent that is oxygen and water resistant, and a cross-linking agent for cross-linking the vinyl substituent of one copolymer with the vinyl substituent of another copolymer.

In an embodiment, a kit for producing an oxygen and water resistant coating includes at least one copolymer of ethylene and substituted vinyl, and a cross-linking agent for cross-linking the vinyl substituent of one copolymer with the vinyl substituent of another copolymer. The substituted vinyl includes at least one vinyl substituent that is oxygen and water resistant.

In an embodiment, a method for producing an oxygen and water resistant coating includes forming copolymers of ethylene and substituted vinyl, wherein the substituted vinyl includes at least one vinyl substituent that is oxygen and water resistant. The method also includes mixing the copolymers with a cross-linking agent for cross-linking the vinyl substituent of one copolymer with the vinyl substituent of another copolymer to cross-link the copolymers.

### BRIEF DESCRIPTION OF THE FIGURES

FIGS. 1A and 1B depict general illustration of, respectively, an OLED and a coated OLED array according to embodiments.

FIGS. 2A and 2B depict copolymerization reactions of ethylene and substituted vinyl according to embodiments.

FIGS. 3A-3D depict substitutions of vinyl alcohols according to an embodiment.

FIG. 4 depicts aldehyde capping of adjacent vinyl alcohols according to an embodiment.

FIGS. 5A-5D depict substitutions of vinyl amines according to an embodiment.

FIG. 6 depicts functionalization of vinyl substituents and subsequent cross-linking of copolymers according to an embodiment.

FIG. 7 depicts functionalization of vinyl substituents and subsequent cross-linking of copolymers according to an embodiment

### DETAILED DESCRIPTION

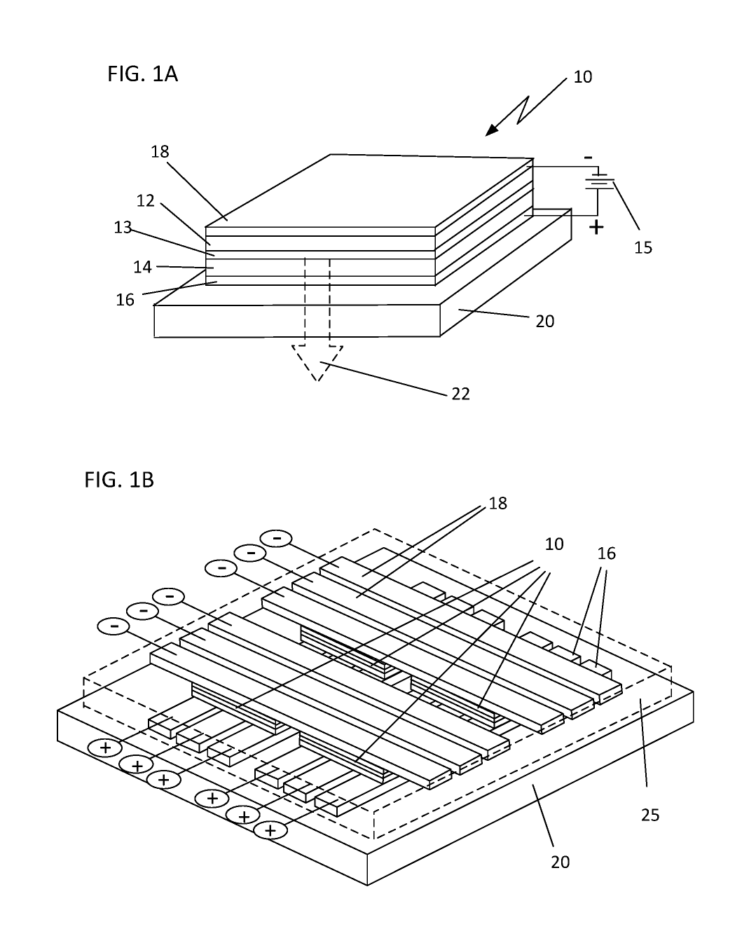

OLEDs (organic light-emitting diodes) are devices that include organic materials that emit light generated by passing electric current through the organic materials. As shown in FIG. 1A, an OLED 10 may have organic material layers 12, 13, and 14 sandwiched between two electrode layers, an anode layer 16 and a cathode layer 18. The layers may be supported on a substrate material 20, that may be a plastic or glass, for example. A power source 15 may be connected with the anode layer 16 and the cathode layer 18 to provide a current through the organic material layers 12, 13, and 14.

The anode 16 may be made of a transparent material that conducts electrical current. Some examples of such a material may include indium tin oxide (ITO), aluminum-doped zinc-oxide (AZO), and indium-doped cadmium-oxide (ICO). The cathode 18 may be produced of a low work function metal, such as calcium, as calcium is electropositive and readily gives up electrons. Other metals that may be used for the cathode include magnesium and lithium.

While not limited to the following, the organic emitters may be provided as the layer 13 and may include small molecules, such as organometallic chelates, fluorescent and phosphorescent dyes, and conjugated dendrimers, or polymers such as derivatives of poly(p-phenylene vinylene), poly(2-methoxy, 5-(2′ ethyl-hexyloxy)-p-phenylenevinylene), and polyfluorene, wherein substitution of side chains onto the polymer backbone may determine the color of emitted light. Layer 12 may be configured as an electron transport layer for transporting electrons from the cathode 18 to the emissive material layer 13. While not limited to the following, an example of a material that may be used for the electron transport layer 12 may include polypyridine. Similarly, layer 14 may be configured as a hole-injection layer to transport holes from the anode 16 to the emissive material layer 13. While not limited to the following, some examples of materials that may be used for the a hole-injection layer 14 may include hole transport polymers ADS250BE, ADS251BE and ADS254BE from American Dye Source, Quebec, Canada. The energy levels of the organic materials may be tuned to maximize the transport of holes from the anode 16 (that may be ITO) and electrons from the cathode 18 (that may be calcium). The holes and electrons meet in the emitting layer 13 to produce the light, represented by dashed arrow 22. The whole device thickness may, in some embodiments, be less than about 500 nm.

A major breakthrough for OLEDs was the AMOLED (active-matrix organic light-emitting diodes) where the emitting material was a metal complex. The metal complexes eventually became the iridium complexes used today in OLEDs. The metal complexes greatly increased device efficiency and luminescent output, and OLEDs were expected to completely replace LCDs in displays and other devices since OLED displays were not angle dependent, offered true blacks, and provided very fast switching to eliminate motion blur. However, OLED usage still remains minimal, but is becoming more common in smart phones and other devices where the displays are typically small. The vast majority of display applications still use LCD technology and a minority use plasma.

As mentioned above, one disadvantage of OLEDs is due to the water and oxygen in the atmosphere. The water and oxygen can be detrimental to OLEDs. With the exception of the ITO layer, every one of the layers of an OLED may be compromised by water and oxygen. OLEDs 10 may require protection from the atmosphere by the use of barrier materials, or coatings 25 that envelop the OLEDs, as schematically depicted in FIG. 1B, and have very low permeability to oxygen and water (less than about 0.03 nanomole/m²/day), to thereby significantly reduce access of water and oxygen to the OLED emitting materials. Suitable materials having both low oxygen and water permeability simultaneously are needed for OLED stability.

Although some efficient barriers have been developed by the food packaging industry, which examples include multi-layer barriers, inorganic deposited barriers, or sandwiched aluminum thin films, these barriers are not be suitable for use in OLEDs because they are not transparent or are difficult to apply. For example, polyvinyl alcohol is an excellent oxygen barrier but is a very poor barrier toward water. Conversely, high density polyethylene is an excellent water barrier but a poor oxygen barrier. Any successful polymeric barrier material for OLEDs would benefit from having low permeability to both oxygen and water simultaneously. A material that has low permeability to one but not the other will be less desirable.

In an embodiment, as represented in FIG. 1B, OLEDs 10 may have an oxygen and water resistant coating 25, wherein the coating includes a copolymer of ethylene and substituted vinyl, and the substituted vinyl includes at least one hydrophobic substituent.

An oxygen and water resistant coating 25 may be produced by taking an ethylene vinyl alcohol copolymer that has excellent oxygen barrier properties but poor water barrier properties, and chemically modifying the copolymer to provide improved barrier properties using any of the following techniques for preparing active pre-polymers:

A. transferring the OH group of the vinyl alcohol segment partially to aliphatic water repellent groups to form substituents such as OCH₃, O-Butyl, O-Cetyl, OSi(CH₃)₃—(substituting vinyl alcohol co-monomer partially with other co-monomers bearing suitable water repellent groups);

B. transferring the OH group of the vinyl alcohol segment, either fully or partially, to acetal, butyral, or furfural derivatives;

C. transferring the OH group of the vinyl alcohol segment, either fully or partially, to grafted side chains with liquid crystal structures; and

D. transferring the OH group of the vinyl alcohol, by reaction with cyanogen halide, to form a cross-linkable cyanate group that is cross-linkable with other polymeric resins such as epoxy resins, maleimide, unsaturated polyesters, melamine resins, or phenolic resins.

Alternatively, a polymeric coating may be produced by taking an ethylene vinyl amine copolymer that has excellent oxygen barrier properties, and chemically modifying the copolymer to give pre-polymers having improved barrier properties by any of the following:

E. transferring the NH₂ group of the vinyl amine segment partially to aliphatic water repellent groups to form substituents such as N(CH₃)₂, N—(C₄H₉)₂, N—(C₁₆H₃₃)₂, N(Si(CH₃)₃)₂—(substituting vinyl amine co-monomer partially with other co-monomers bearing suitable water repellent/oxygen barrier groups); and

F. modifying the amine group to a cross-linkable isocyanate group that is cross-linkable with other polymeric resins.

All of the above-mentioned functional groups may enhance the water barrier properties and/or oxygen barrier properties of the polymer, as they are either non-hydrogen bonded groups and highly cross-linked with no side products that lead to porosity, or are highly water repellent functional groups and are also excellent oxygen barriers. Any of the pre-polymers may be applied as viscous liquids and cured photolytically or catalytically in situ. As examples, the cyanate derivatives may undergo curing reaction with epoxy resins, maleimide, unsaturated polyesters, melamine resins, or phenolic resins. The final compositions may be cured thermally by using infrared radiation, or by UV radiation, applying standard procedures and equipment commonly used in photo and catalytic curing of epoxy, acrylates and unsaturated polyesters.

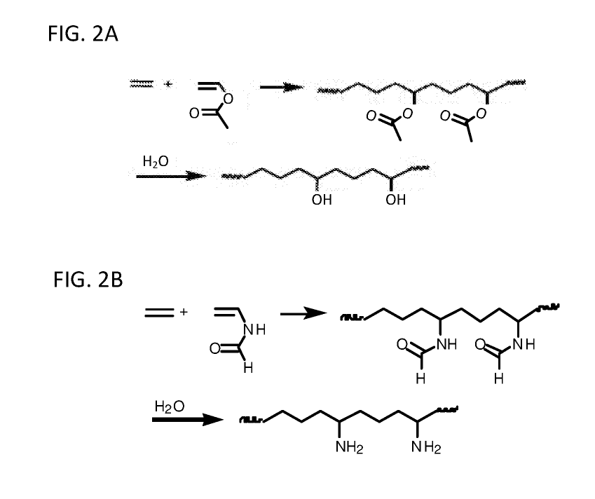

In one embodiment, such a coating 25 may be derived from ethylene-vinyl acetate copolymers. As represented in FIG. 2A, ethylene may be copolymerized with the vinyl acetate and then subsequently hydrolyzed to form ethylene-vinyl alcohol copolymers. The resultant copolymers may provide low oxygen transmission rates, primarily due to the vinyl alcohol. The vinyl alcohol portion of the polymer, however, may allow for some water transmission. Thus, the vinyl alcohol portion of the polymers may be functionalized, either fully or partially, with a hydrophobic substituent (that may also provide additional oxygen barrier protection) to modify the polymer chemically and/or structurally to increase barrier properties to water and oxygen, and provide a coating material with suitable barrier properties to protect the OLEDs from both water and oxygen, and subsequently increase device longevity.

Such a coating 25 may also be derived from ethylene-vinyl formamide copolymers, wherein, as shown in FIG. 2B, ethylene may be copolymerized with vinyl formamide and then subsequently hydrolyzed to ethylene-vinyl amine. While amines have hydrophilicity, the amines may be functionalized with a hydrophobic substituent to modify the polymer chemically and/or structurally to increase barrier properties to both water and oxygen.

OLEDs having a coating of an ethylene-substituted vinyl copolymer may thereby have decreased exposure to both oxygen and water. The coating, at ambient atmospheric pressure of about 1 atm, may be configured to have an oxygen transmission rate of about 0.001 nanomole/m²/day to about 0.03 nanomole/m²/day, and a water vapor transmission rate of about 0.001 nanomole/m²/day to about 0.03 nanomole/m²/day. In embodiments, a coating may be configured to have, at 1 atm pressure, an oxygen transmission rate equal to or less than about 0.001 nanomole/m²/day, and a water vapor transmission rate equal to or less than about 0.001 nanomole/m²/day.

It has been determined that an ethylene-substituted vinyl copolymer having ethylene present in the copolymer in an amount of about 30 wt % to about 40 wt % may provide improved barrier properties for protecting OLEDs from oxygen and water. Some examples of hydrophobic substituent groups that may be covalently provided on the vinyl include hydrophobic moieties of alkyls, acyls, silyls, alkenyls, cycloalkyls, aryls, alkaryls, aralkyls, fluoryl, aralkylamino, alkylamino, dialkylamino, liquid crystal segment, substituted melamine, and combinations thereof.

In an embodiment, the alkaryls may include liquid crystals, or liquid crystal segments. The copolymers may be modified with liquid crystals, as liquid crystals provide for high barrier properties to both oxygen and water. Liquid crystals by themselves may typically be difficult to work with, however, by attachment to the copolymer backbone as discussed above, the liquid crystals may be made usable for barrier coatings.

The hydrophobic substituent may be connected with the substituted vinyl by one of an ether linkage, an ester linkage, an amine linkage, an imine linkage, a urethane linkage, and a cyanate linkage. In an embodiment wherein the linkage may be an ether linkage, the copolymer may be at least one of a random copolymer, an alternating copolymer, and a block copolymer, and have a structural formula represented by:

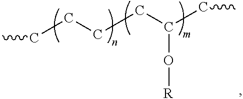

wherein n≧1, m≧1, at least a first portion of R is H, and at least a second portion of R is the hydrophobic substituent. In various embodiments, the hydrophobic substituent may be selected from the group consisting of: alkyl, acyl, silyl, alkenyl, cycloalkyl, aryl, alkaryl, fluoryl, aralkylamino, alkylamino, dialkylamino, liquid crystal segment, substituted melamine, and combinations thereof. A molar ratio of ethylene to substituted vinyl may be about 0.7:1.3 to about 1.3:0.7.

As examples, various copolymers of A and B units may be generally represented as follows:

random copolymers: -A-B-B-A-B-A-A-A-B-A-B-B-A-A-B-B-B-B-

alternating copolymers: -A-B-A-B-A-B-A-B-A-B-A-B-

block copolymers: -A-A-A-A-A-A-A-A-A-B-B-B-B-B-B-B-B-B-B-

Within the context herein, and as an example only, (A) may represent ethylene moieties, and (B) may represent substituted vinyl moieties.

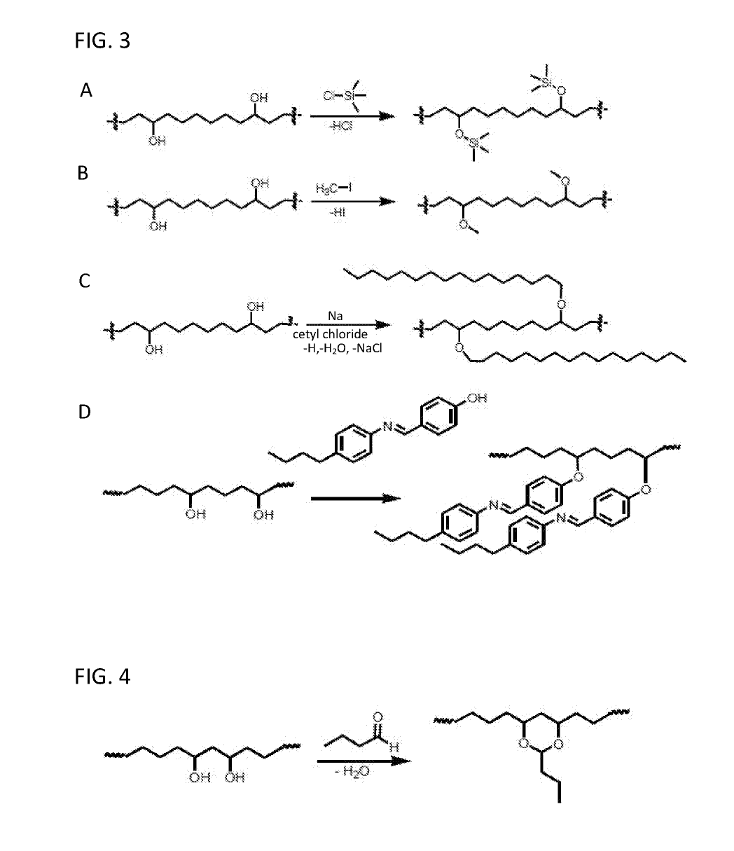

In some embodiments, the hydrophobic substituent may be selected from the group consisting of C1-C20 alkyl, C1-C4 monoalkylsilyl, C1-C4 dialkylsilyl, C1-C4 trialkylsilyl, C1-C4 monoalkoxysilyl, C1-C4 dialkoxysilyl, C1-C4 trialkoxysilyl, and combinations thereof. While not limited to the following, some examples of hydrophobic substituents may include methyl, ethyl, propyl, butyl, cetyl, trimethylsilyl, N-(4-methoxybenzylidene)-4-butylanilinyl. FIG. 3 provides some representative polymer structures wherein the vinyl alcohol copolymer is substituted with A) silyl, B) methyl, C) cetyl moieties, and D) the liquid crystal N-(4-methoxybenzylidene)-4-butylanilinyl

In ethylene-vinyl alcohol copolymers, there may be a high likelihood that two or more vinyl alcohol segments may be adjacent to each other. As represented in FIG. 4, adjacent vinyl alcohol moieties may be capped with aldehydes. Some examples of aldehydes may include, but are not limited to ethanal (acetaldehyde—C₂H₄O), propanal (propionaldehyde—C₃H₆O), butanal (butyraldehyde—C₄H₈O), neopentaldehyde (2,2 dimethylpropanal—C₅H₁₀O), neohexanaldehyde (2,2 dimethylbutanal—C₆H₁₂O), furfural (furan-2-carbaldehyde—C₅H₄O₂). Additional ones of the vinyl alcohols may be substituted, as discussed above, with a copolymer that may be at least one of a random copolymer, an alternating copolymer, and a block copolymer. Such a capped copolymer may have a structural formula represented by:

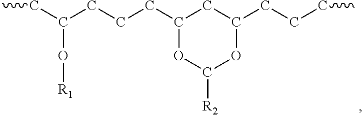

wherein R₁ is selected from the group consisting of: H, alkyl, silyl, alkenyl, cycloalkyl, aryl, alkaryl, aralkyl, liquid crystal segment, substituted melamine, amine, alkylamine, dialkylamine, and combinations thereof, and R₂ is selected from the group consisting of: alkyl, alkenyl, aryl, alkaryl, aralkyl, cycloalkyl, and combinations thereof. Any of the alkyl, alkenyl, aryl, alkaryl, aralkyl, cycloalkyl groups may be halogenated, such as with fluorine.

In an embodiment of such capped copolymers, a molar ratio of ethylene to substituted vinyl may be about 0.7:1.3 to about 1.3:0.7. In addition, R₁ may be at least one of H, methyl, propyl, butyl, cetyl, trimethylsilyl, N-(4-methoxybenzylidene)-4-butylanilinyl, amino, alkylamino, dialkylamino, and substituted melamine, and R₂ may be at least one of methyl, ethyl, propyl, butyl, isobutyl, neopentyl, and furanyl.

In an embodiment wherein the linkage may be an amine linkage the copolymer may be at least one of a random copolymer, an alternating copolymer, and a block copolymer, and may have a structural formula represented by:

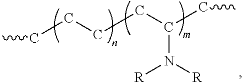

wherein n≧1, m≧1, and each R is a hydrophobic substituent. As discussed previously, the hydrophobic substituent may be one of alkyl, acyl, silyl, alkenyl, cycloalkyl, aryl, alkaryl, aralkyl, and combinations thereof, and a molar ratio of ethylene to substituted vinyl may be about 0.7:1.3 to about 1.3:0.7.

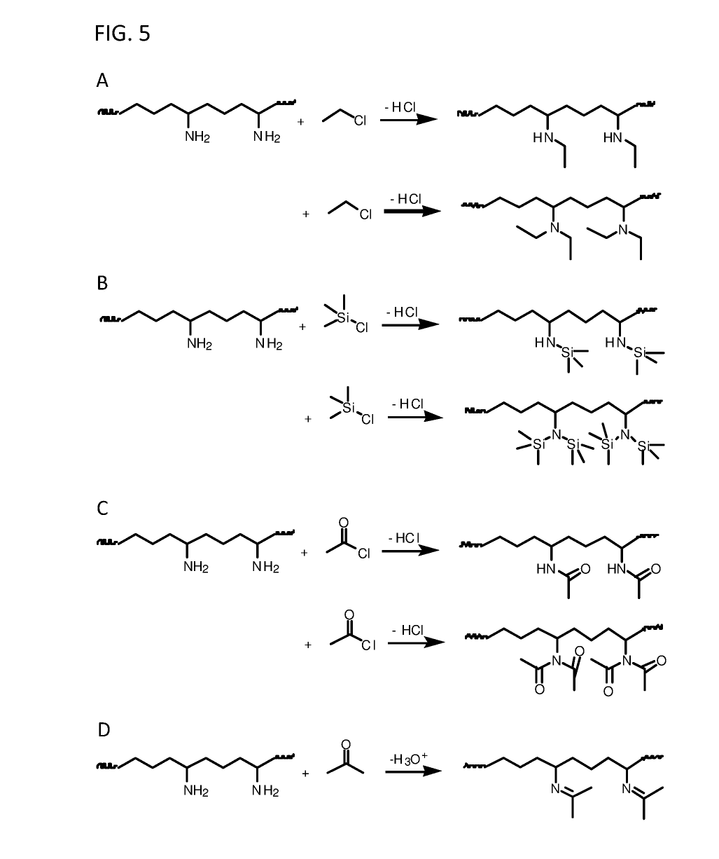

In various embodiments having an amine linkage, the hydrophobic substituent may be selected from the group consisting of C1-C20 alkyl, C1-C4 monoalkylsilyl, C1-C4 dialkylsilyl, C1-C4 trialkylsilyl, C1-C4 monoalkoxysilyl, C1-C4 dialkoxysilyl, C1-C4 trialkoxysilyl, liquid crystal, amino, alkylamino, dialkylamino, substituted melamine, and combinations thereof. While not limited to the following, some examples of the hydrophobic substituent may include methyl, ethyl, propyl, butyl, cetyl, trimethylsilyl, N-(4-methoxybenzylidene)-4-butylanilinyl, and combinations thereof. FIGS. 5A-5C provide representative polymer structures wherein the vinyl amine copolymer is substituted with ethyl (FIG. 5A), silyl (FIG. 5B), and acyl (FIG. 5C) moieties.

In an embodiment wherein the linkage may be an imine linkage, the copolymer may be at least one of a random copolymer, an alternating copolymer, and a block copolymer, and may have a structural formula represented by:

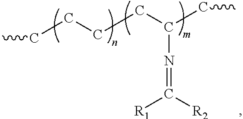

wherein R₁ and R₂ are independently one of H, C1-C20 alkyl, and combinations thereof, n≧1 and m≧1. FIG. 5D provides a representative polymer structures wherein the vinyl copolymer is functionalized with imine substituents.

Any of the above-described copolymers may be used to provide a coating to protect an OLED, or essentially any other type of device or material that may require an oxygen and water resistant coating. The copolymers may be applied by coating the OLED (or other device or material) with a liquid form of the copolymers, and then curing the polymer coating to solidify the coating.

In an embodiment, a method for producing a barrier coating for protecting organic light-emitting diodes from oxygen and water, may include forming a copolymer of ethylene and substituted vinyl, wherein the substituted vinyl includes a hydrophobic substituent.

In one embodiment, the substituted vinyl may be vinyl alcohol, whereby the copolymer may be a copolymer of ethylene and vinyl alcohol, and the forming of the copolymer may include functionalizing a portion of the vinyl alcohol with the hydrophobic substituent. The functionalizing may include converting the alcohol substituent of at least a portion of the vinyl alcohol to at least one of an ether linkage, an amine linkage, an ester linkage, a urethane linkage, and a cyanate linkage, with essentially any of the hydrophobic substituents as discussed above.

One method for producing an ethylene-vinyl alcohol copolymer may include first producing an ethylene-vinyl acetate copolymer. As discussed above, the molar ratio of ethylene to vinyl acetate may be about 0.7:1.3 to about 1.3:0.7. The ethylene-vinyl acetate copolymer may then be hydrolyzed to produce the ethylene-vinyl alcohol copolymer.

In an embodiment, the copolymer may be formed by copolymerizing ethylene with a substituted vinyl, wherein the substituted vinyl may be at least one of vinyl alkyl ether wherein the alkyl is C1-C20 alkyl, vinyl trialkylsilyl ether wherein the alkyl is C1-C4 alkyl, and vinyl substituted with liquid crystal segments, an amino, an alkylamino group, a dialkylamino group, a substituted melamine, a fluoride, and combinations thereof.

In another embodiment, the substituted vinyl may be vinyl amine, whereby the copolymer may be a copolymer of ethylene and vinyl amine, and the forming of the copolymer may include functionalizing the vinyl amines of the ethylene-vinyl amine copolymer with the hydrophobic substituent. The functionalizing may include converting at least a portion of the vinyl amines to one of an amine linkage with the hydrophobic substituent, and an imine linkage with the hydrophobic substituent, wherein the hydrophobic substituent may be essentially any of the hydrophobic substituents as disclosed herein.

The ethylene-vinyl amine copolymer may be produced by first copolymerizing ethylene and vinyl formamide to producing an ethylene-vinyl formamide copolymer. As discussed above, the molar ratio of ethylene to vinyl formamide may be about 0.7:1.3 to about 1.3:0.7. The ethylene-vinyl formamide copolymer may then be hydrolyzed to produce the ethylene-vinyl alcohol copolymer. Alternatively, ethylene may be copolymerized with vinyl amine, and the vinyl amine may be substituted at either one, or both, of the hydrogen positions with alkyl, acyl, silyl, alkenyl, cycloalkyl, aryl, alkaryl, aralkyl, amino, alkylamino, dialkylamino, substituted melamine, liquid crystal, fluorinated groups, and combinations thereof. In embodiments, the substituent may be C1-C20 alkyl, C1-C4 monoalkylsilyl, C1-C4 dialkylsilyl, C1-C4 trialkylsilyl, C1-C4 monoalkoxysilyl, C1-C4 dialkoxysilyl, C1-C4 trialkoxysilyl, amino, alkylamino, dialkylamino, and combinations thereof. As non-limiting examples, the substituent may be methyl, ethyl, propyl, butyl, cetyl, trimethylsilyl, N-(4-methoxybenzylidene)-4-butylanilinyl, amino, alkylamino, dialkylamino, substituted melamine, fluorinated groups and combinations thereof.

Any of the described coatings may be provided as a kit for producing an oxygen and water resistant coating. In general, such a kit may include at least copolymers of ethylene and substituted vinyl, and hydrophobic moieties for functionalizing at least a portion of the substituted vinyl.

In an embodiment, the substituted vinyl may be vinyl alcohol and the copolymers may be ethylene-vinyl alcohol copolymers. Alternatively, the substituted vinyl may be vinyl amine and the copolymers may be ethylene-vinyl amine copolymers. The hydrophobic moieties may be alkyls, acyls, silyls, alkenyls, cycloalkyls, aryls, alkaryls, aralkyls, liquid crystal segments, amino, alkylamino, dialkylamino, substituted melamine, fluorinated groups, and combinations thereof. In various embodiments, the hydrophobic moieties may be halogenates, ketones, aldehydes, and alcohols of selected moieties of the group consisting of: methyl, propyl, cetyl, trimethylsilyl, N-(4-Methoxybenzylidene)-4-butylanilinyl, amino, alkylamino, dialkylamino, liquid crystal segments, amino, alkylamino, dialkylamino, substituted melamine, fluorinated groups and combinations thereof.

A step in the production of the OLEDs may include mixing of the at least two components of the kit (the copolymers and the hydrophobic moieties) under conditions that will allow the hydrophobic moieties to react with and bind to the vinyl substituent. The liquid coating produced may then be applied to OLEDs and cured to produce a protective coating on the OLEDs.

Another type of coated organic light-emitting diode may include an organic light-emitting diode that is coated with an oxygen and water resistant coating of cross-linked copolymers of ethylene and substituted vinyl, wherein the substituted vinyl includes at least one vinyl substituent that is oxygen and water resistant. The copolymers may be linked via the vinyl substituents by a cross-linking agent.

As non-limiting examples, the vinyl substituent may be cyanate, isocyanate, nitrile, or combinations thereof, and the vinyl substituents may be cross-linked by one or more of epoxy, maleimide, unsaturated polyester, melamine, phenolic resin and combinations thereof.

Such a cross-linked coating may also be configured to have an oxygen transmission rate of about 0.001 nanomole/m²/day to about 0.03 nanomole/m²/day, and a water vapor transmission rate of about 0.001 nanomole/m²/day to about 0.03 nanomole/m²/day. Alternatively, by optimizing the vinyl substituents and cross-linking agents, such a cross-linked coating may be configured to have an oxygen transmission rate equal to or less than about 0.001 nanomole/m²/day, and a water vapor transmission rate equal to or less than about 0.001 nanomole/m²/day. In an embodiment, the copolymer may have a weight ratio of ethylene to substituted vinyl of about 30:70 to about 40:60.

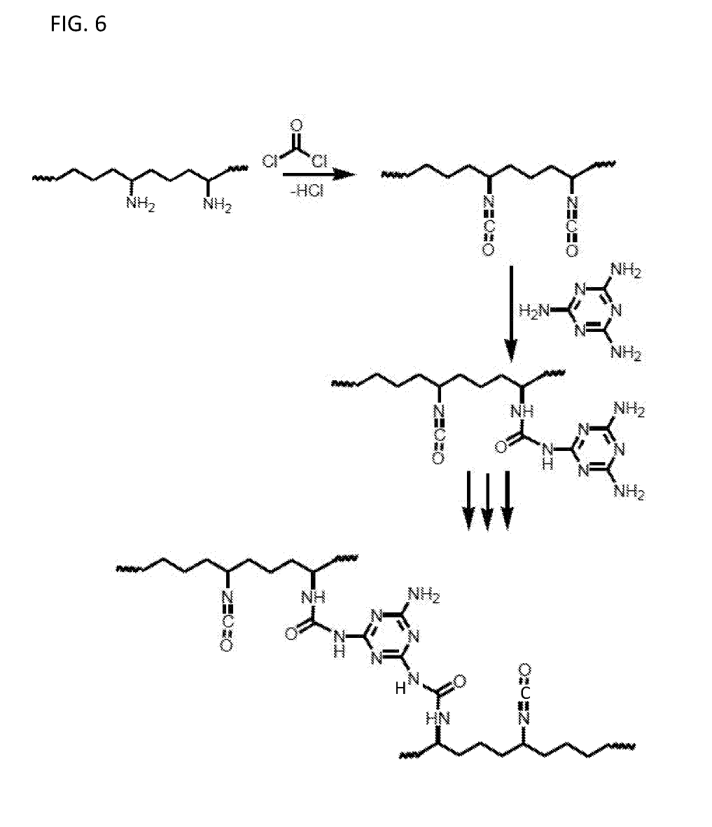

In an embodiment, copolymers of ethylene-vinyl amine may be converted to the isocyanate which is a crosslinkable group. This may be done by copolymerizing ethylene with vinyl formamide to produce a copolymer of ethylene and vinyl formamide, with subsequent hydrolysis of vinyl formamide to amine groups to produce an ethylene-vinyl amine copolymer as shown in FIG. 2B. As depicted in FIG. 6, phosgene may then be used to convert the amine groups to isocyanates to produce an ethylene-vinyl isocyanate copolymer. As shown as an example in FIG. 6, the isocyanates may be cross-linked via melamine

A cross-linked coating having isocyanate as the cross-linkable group may be structurally represented by the formula:

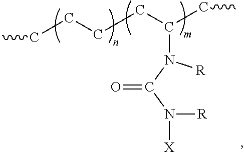

wherein n≧1, m≧1, X is a cross-linking agent having a free-nitrogen to bond with the isocyanate, and is at least one of epoxy, maleimide, unsaturated polyester, melamine, and phenolic resin, and each R is a hydrophobic substituent. As discussed previously, the hydrophobic substituent may be one of alkyl, acyl, silyl, alkenyl, cycloalkyl, aryl, alkaryl, aralkyl, and combinations thereof.

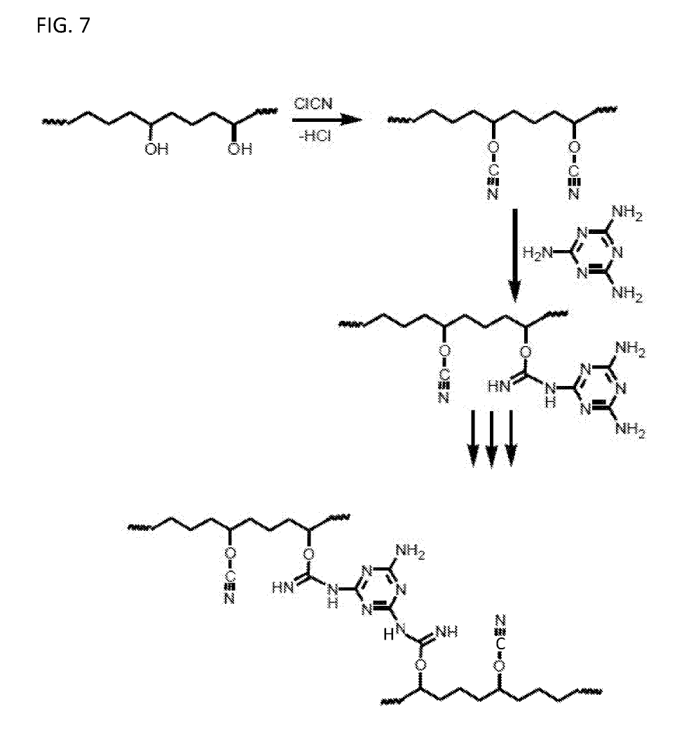

In an alternative embodiment, copolymers of ethylene-vinyl hydroxide may be converted to the cyanate which is a crosslinkable group. This may be done by copolymerizing ethylene with vinyl acetate to produce a copolymer of ethylene and vinyl acetate, with a subsequent hydrolysis of vinyl acetate to the alcohol to produce an ethylene-vinyl alcohol copolymer as shown in FIG. 2A. As depicted in FIG. 7, cyanogen chloride (or other cyanogen halides) may then be used to convert the alcohols to the cyanate moiety to produce an ethylene-vinyl cyanate copolymer. In an alternative embodiment, copolymers of ethylene and vinyl cyanate may be made directly by copolymerizing ethylene and vinyl cyanate. As shown as an example in FIG. 7, the cyanates may be cross-linked with melamine and epoxy.

A cross-linked coating having cyanate as the cross-linkable group may be structurally represented by the formula:

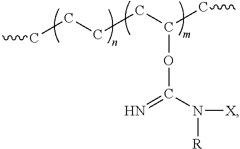

wherein n≧1, m≧1, X is a cross-linking agent having a free-nitrogen to bond with the cyanate, and is at least one of epoxy, maleimide, unsaturated polyester, melamine, and phenolic resin, and R is a hydrophobic substituent. As discussed previously, the hydrophobic substituent may be one of alkyl, acyl, silyl, alkenyl, cycloalkyl, aryl, alkaryl, aralkyl, and combinations thereof.

A kit for producing an oxygen and water resistant barrier material may also be provided that includes the cross-linkable copolymers. Such a kit may have at least one copolymer of ethylene and substituted vinyl, wherein the substituted vinyl includes at least one vinyl substituent that is oxygen and water resistant. The vinyl substituent may be a cross-linkable substituent, and include a cross-linking agent for cross-linking the vinyl substituent of one copolymer with the vinyl substituent of another copolymer.

The copolymer in the kit may include ethylene present in the copolymer in an amount of about 30 wt % to about 40 w %, and the vinyl substituent may be at least one substituent selected from the group consisting of a cyanate, an isocyanate, a nitrile, and combinations thereof. The cross-linking agent may be, but is not limited to, epoxy, maleimide, unsaturated polyester, melamine, phenolic resin, and combinations thereof.

An OLED, or any other material that may need oxygen and/or water protection, may be protected by coating the OLED (or other material) with a coating such as one that may be formed from the components of the kit. A barrier coating may be prepared by mixing at least one copolymer of ethylene and substituted vinyl, wherein the substituted vinyl includes at least one vinyl substituent that is oxygen and water resistant, with a cross-linking agent for cross-linking the vinyl substituent of one copolymer with the vinyl substituent of another copolymer. The coating, in liquid form, may be deposited onto the OLED (or other material), and cured to cross-link the copolymers and form a solid surface coating over the OLED (or other material).

Use of the described methods and materials can result in a reduction or elimination of damage from water and oxygen to a protected OLED relative to the same or similar OLED without the described protective methods and materials. The degree of damage can generally be reduced by any amount. For example, the degree of damage can be reduced by at least about 10%, at least about 20%, at least about 30%, at least about 40%, at least about 50%, at least about 60%, at least about 70%, at least about 80%, at least about 90%, at least about 95%, at least about 96%, at least about 97%, at least about 98%, at least about 99%, and in an ideal situation, about 100% reduction (complete elimination of damage).

### EXAMPLES

### Example 1

### An Oxygen and Water Resistant Coating

An oxygen and water resistant coating will include a copolymer of ethylene and substituted vinyl having a molar ratio of ethylene to vinyl component of about 1:1, and about 40% of the substituted vinyl being vinyl alcohol and 60% being methyl vinyl ether. The vinyl alcohol components provide an oxygen barrier and the methyl vinyl ether and ethylene components provide a water barrier. The copolymer will be applied as a liquid and will be photolytically cured to harden into a protective coating.

### Example 2

### A Kit for Producing an Oxygen and Water Resistant Coating

A kit for producing an oxygen and water resistant coating will include at least two kit components. A first kit component will include copolymers of ethylene and vinyl alcohol having a molar ratio of ethylene to vinyl of about 1:1. A second kit component will include at least one substituent for modifying the vinyl alcohol to methyl ether (using a procedure such as that described in the following example 3). The second component may be methyl iodide in an amount sufficient to transfer about 60% of the vinyl alcohol sites to methyl ether linkages. The components will be configured to be mixed together on site to produce a molten polymer that may be applied to an article to be protected by a high pressure spraying technique.

### Example 3

### A Method for Producing an Oxygen and Water Resistant Coating

A coating that provides protection from water and oxygen will be produced by forming a copolymer of ethylene and a substituted vinyl, wherein the substituted vinyl will include a hydrophobic and oxygen barrier substituent. As represented in FIG. 2A, a random copolymer of ethylene and vinyl acetate is formed according to standard procedures. The ethylene vinyl acetate copolymers will then be hydrolyzed to convert the acetate substituents to alcohols and produce ethylene-vinyl alcohol copolymers having a molar ratio of ethylene to vinyl alcohols of about 1:1.

The ethylene-vinyl alcohol copolymers may be dissolved in tetrahydrofuran and reacted with a sodium metal suspension under dry conditions to replace alcohol hydrogen with sodium. The unreacted sodium suspension is removed and, as represented in FIG. 3C, cetyl chloride is added portion-wise with efficient mixing to form cetyl ether linkages. Sodium chloride, solvent, and unreacted cetyl chloride are separated. An amount of cetyl chloride added will be about 50 mol % of the vinyl alcohol present in the copolymer to convert about 50% of the vinyl alcohols to cetyl ether linkages. The molten coating will be sprayed onto a surface to be protected using high pressure spraying technology.

### Example 4

### Coated Organic Light Emitting Diodes

The coating of Example 3 will be applied to an organic light emitting diode array. OLEDs will be constructed having an emissive layer of poly(p-phenylene vinylene) between an electron transport layer of polypyridine and a hole transport polymer such as American Dye polymer ADS250BE. Cathode strips of magnesium will be deposited on the electron transport layer, and anode strips of ITO will be deposited on the hole transport polymer.

An array of the OLEDs will be deposited onto a glass substrate, and the molten coating material of Example 3 will be sprayed over the OLEDS to seal the OLEDs with the glass substrate and inhibit penetration of atmospheric oxygen and water to the OLEDs.

### Example 5

### Cross-Linked Coating

An oxygen and water resistant coating will include cross-linked copolymers of ethylene and vinyl amine, with a molar ratio of ethylene to vinyl amine of about 0.7:1.3. The substituted vinyl amine will be transferred to vinyl isocyanate. The isocyanates will be cross-linked by melamine. The copolymer will be applied as a liquid and as cross-linking occurs, will harden into a protective coating. An alternative application method involves spraying the ethylene-isocyanate copolymers to the OLED surface then subjecting the surface to sublimed vapor of melamine The curing and crosslinking reaction takes place instantly forming protected OLED surfaces.

### Example 6

### A Kit for Cross-Linked Coatings

A kit for producing an oxygen and water resistant coating will include at least two kit components. A first kit component will include copolymers of ethylene and vinyl isocyanate having a molar ratio of ethylene to vinyl isocyanate of about 0.7:1.3. The ethylene-isocyanate copolymers will be provided as a liquid to be sprayed onto a surface to be protected. A second kit component will include melamine for cross-linking the copolymers. The melamine will be provided as a solid to be sublimed to a vapor for contacting the sprayed-on copolymer to cross-link the copolymer.

### Example 7

### A Method for Producing an Oxygen and Water Resistant Coating

A coating that provides protection from water and oxygen will be produced by forming a copolymer of ethylene and a substituted vinyl, wherein the substituted vinyl will include a hydrophobic and oxygen barrier substituent. As represented in FIG. 2B, a random copolymer of ethylene and vinyl formamide will be formed by introducing ethylene and vinyl formamide at a molar ratio of about 0.7:1.3 into a reaction vessel according to standard procedures. The resultant ethylene vinyl formamide copolymers will be hydrolyzed to form ethylene vinyl amines, and the ethylene vinyl amines will be subjected to phosgene gas or carbon monoxide to convert the amine substituents to isocyanates to produce ethylene-vinyl isocyanate copolymers having a molar ratio of ethylene to vinyl isocyanate of about 0.7:1.3.

As represented in FIG. 6, the molten ethylene-vinyl isocyanate copolymers will be sprayed under high pressure onto the surface to be protected, and the surface is subjected to the sublimed melamine vapor to cross-link the isocyanates and harden the coating.

### Example 8

### Coated Organic Light Emitting Diodes

The coating of Example 7 will be applied to an organic light emitting diode array. OLEDs will be constructed having an emissive layer of poly(p-phenylene vinylene) between an electron transport layer of polypyridine and a hole transport polymer such as American Dye polymer ADS250BE. Cathode strips of magnesium will be deposited on the electron transport layer, and anode strips of ITO will be deposited on the hole transport polymer.

An array of the OLEDs will be deposited onto a surface of a glass substrate. Molten ethylene-vinyl isocyanate copolymers will be sprayed under high pressure and dry condition onto the surface to coat the OLEDs. The surface will be subjected to sublimed melamine vapor which will react instantly with the isocyanates to form a strong barrier coating over the OLEDs to seal the OLEDs with the glass substrate and inhibit penetration of atmospheric oxygen and water to the OLEDs.

This disclosure is not limited to the particular systems, devices and methods described, as these may vary. The terminology used in the description is for the purpose of describing the particular versions or embodiments only, and is not intended to limit the scope.

In the above detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only, and is not intended to be limiting.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. Nothing in this disclosure is to be construed as an admission that the embodiments described in this disclosure are not entitled to antedate such disclosure by virtue of prior invention. As used in this document, the term “comprising” means “including, but not limited to.”

While various compositions, methods, and devices are described in terms of “comprising” various components or steps (interpreted as meaning “including, but not limited to”), the compositions, methods, and devices can also “consist essentially of” or “consist of” the various components and steps, and such terminology should be interpreted as defining essentially closed-member groups.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

Various of the above-disclosed and other features and functions, or alternatives thereof, may be combined into many other different systems or applications. Various presently unforeseen or unanticipated alternatives, modifications, variations or improvements therein may be subsequently made by those skilled in the art, each of which is also intended to be encompassed by the disclosed embodiments.

1. A coated organic light-emitting diode comprising:
at least one organic light-emitting diode; and
an oxygen and water resistant coating on the organic light-emitting diode, the coating comprising a copolymer of ethylene and substituted vinyl, wherein the substituted vinyl comprises at least one hydrophobic substituent selected from the group consisting of alkyls, silyls, alkenyls, cycloalkyls, aryls, alkaryls, aralkyls, fluoryl, aralkylamino, alkylamino, dialkylamino, substituted melamine, and combinations thereof.

2. The coated organic light-emitting diode of claim 1, wherein:
the coating has an oxygen transmission rate of about 0.001 nanomole/m²/day to about 0.03 nanomole/m²/day; and
the coating has a water vapor transmission rate of about 0.001 nanomole/m²/day to about 0.03 nanomole/m²/day.

3. The coated organic light emitting diode of claim 1, wherein the coating has an oxygen transmission rate equal to or less than about 0.001 nanomole/m²/day.

4. The coated organic light emitting diode of claim 1, wherein the coating has a water vapor transmission rate equal to or less than about 0.001 nanomole/m²/day.

5. The coated organic light-emitting diode of claim 1, wherein the copolymer comprises a weight ratio of ethylene to substituted vinyl of about 30:70 to about 40:60.

6. (canceled)

7. The coated organic light-emitting diode of claim 1, wherein the at least one hydrophobic substituent comprises an alkaryl.

8. (canceled)

9. The coated organic light-emitting diode of claim 1, wherein the copolymer has a structural formula represented by: 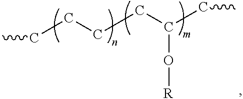
wherein n≧1, m≧1, and R is H or the hydrophobic substituent.

10.-11. (canceled)

12. The coated organic light-emitting diode of claim 1, wherein the hydrophobic substituent is selected from the group consisting of C1-C20 alkyl, C1-C4 monoalkylsilyl, C1-C4 dialkylsilyl, C1-C4 trialkylsilyl, C1-C4 monoalkoxysilyl, C1-C4 dialkoxysilyl, C1-C4 trialkoxysilyl, and combinations thereof.

13. (canceled)

14. The coated organic light-emitting diode of claim 1, wherein the copolymer has a structural formula represented by: 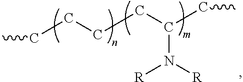
wherein n≧1, m≧1, and R is the hydrophobic substituent.

15.-18. (canceled)

19. The coated organic light-emitting diode of claim 1, wherein the copolymer has a structural formula represented by: 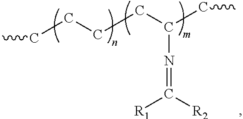
wherein R₁ and R₂ are independently selected from H, C1-C20 alkyl, and combinations thereof, and n≧1 and m≧1.

20. The coated organic light-emitting diode of claim 1, wherein the copolymer has a structural formula represented by: 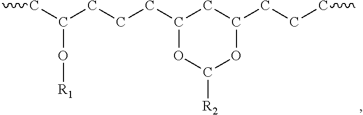
wherein R₁ is selected from the group consisting of: H, alkyl, silyl, alkenyl, cycloalkyl, aryl, alkaryl, aralkyl, liquid crystal segment, amino, alkylamino, dialkylamino, substituted melamine, and combinations thereof, and R₂ is selected from the group consisting of: alkyl, alkenyl, aryl, alkaryl, aralkyl, cycloalkyl, fluorinated alkyl, fluorinated alkenyl, fluorinated aryl, fluorinated alkaryl, fluorinated aralkyl, fluorinated cycloalkyl and combinations thereof.

21.-34. (canceled)

35. A method for protecting an organic light-emitting diode from oxygen and water, the method comprising:
coating the organic light emitting diode with an oxygen and water resistant coating comprising a copolymer of ethylene and substituted vinyl, wherein the substituted vinyl comprises at least one hydrophobic substituent selected from the group consisting of alkyls, silyls, alkenyls, cycloalkyls, aryls, alkaryls, aralkyls, fluoryl, aralkylamino, alkylamino, dialkylamino, liquid crystal segment, substituted melamine, and combinations thereof; and
curing the polymer coating.

36. The method of claim 35, wherein the copolymer comprises a molar ratio of ethylene to substituted vinyl of about 0.7:1.3 to about 1.3:0.7.

37. (canceled)

38. The method of claim 35, wherein the coating comprises coating with a copolymer having the hydrophobic substituent connected to the substituted vinyl by an ether linkage, an ester linkage, a urethane linkage, an amine linkage, an imine linkage, and a cyanate linkage.

39.-40. (canceled)

41. The method of claim 35, wherein the coating comprises coating with a copolymer having a structural formula represented by: 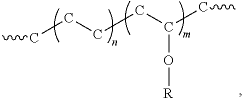
wherein n≧1, m≧1, and R is H or the hydrophobic sub stituent.

42. (canceled)

43. The method of claim 35, wherein the hydrophobic substituent is selected from the group consisting of: C1-C20 alkyl, C1-C4 monoalkylsilyl, C1-C4 dialkylsilyl, C1-C4 trialkylsilyl, C1-C4 monoalkoxysilyl, C1-C4 dialkoxysilyl, C1-C4 trialkoxysilyl, and combinations thereof.

44. (canceled)

45. The method of claim 35, wherein the coating comprises coating with a copolymer having a structural formula represented by: 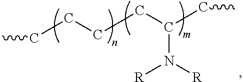
wherein n≧1, m≧1, R is the hydrophobic substituent.

46.-47. (canceled)

48. The method of claim 35, wherein the coating comprises coating with a copolymer having a structural formula represented by: 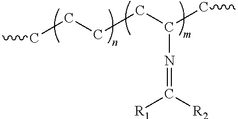
wherein R₁ and R₂ are independently one of H, C1-C20 alkyl, and combinations thereof, and n≧1 and m≧1.

49.-56. (canceled)

57. A method for producing an oxygen and water resistant coating, the method comprising forming a copolymer comprising ethylene and vinyl alcohol, wherein the vinyl alcohol comprises at least one hydrophobic and oxygen barrier substituent; and
functionalizing a portion of the vinyl alcohol with the hydrophilic and oxygen barrier substituent.

58. (canceled)

59. (canceled)

60. The method of claim 57, wherein forming the copolymer comprises forming a copolymer having an hydrophobic and an oxygen barrier substituent selected from the group consisting of: alkyls, acyls, silyls, alkenyls, cycloalkyls, aryls, alkaryls, aralkyls, liquid crystal segments, amino, alkylamino, dialkylamino, substituted melamine, fluorinated groups and combinations thereof.

61. (canceled)

62. The method of claim 57, wherein forming the copolymer comprises hydrolyzing an ethylene-vinyl acetate copolymer.

63.-64. (canceled)

65. The method of claim 57, wherein forming the copolymer comprises forming a copolymer having an hydrophobic and an oxygen barrier substituent selected from the group consisting of: C1-C20 alkyl, C1-C20 acyl, C1-C4 monoalkylsilyl, C1-C4 dialkylsilyl, C1-C4 trialkylsilyl, C1-C4 monoalkoxysilyl, C1-C4 dialkoxysilyl, C1-C4 trialkoxysilyl, liquid crystal, and combinations thereof.

66. The method of claim 57, wherein forming the copolymer comprises copolymerizing ethylene with the substituted vinyl alcohol, wherein the substituted vinyl alcohol is at least one of vinyl alkyl ether wherein the alkyl is C1-C20 alkyl, vinyl trialkylsilyl ether wherein the alkyl is C1-C4 alkyl, and vinyl substituted with liquid crystal segments, an amino, an alkylamino group, a dialkylamino group, a substituted melamine, a fluoryl, and combinations thereof.

67.-104. (canceled)
